(19) United States
(12) Patent Application Publication
(10) Pub. No.: US 2007/0104003 A1
(43) Pub. Date: May 10, 2007

(54) MEMORY DEVICE WITH AUXILIARY SENSING

(75) Inventor: Uk-Song KANG, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: Samsung Electronics Co., Ltd., Gyeonggid-do (KR)

(21) Appl. No.: 11/549,908

(22) Filed: Oct. 16, 2006

(30) Foreign Application Priority Data
Nov. 8, 2005 (KR) 2005-0106395

(51) Int. Cl. G11C 7/00

(52) U.S. Cl. 365/203

(57) ABSTRACT

A semiconductor memory device may include bit line coupled to a sense amplifier and an auxiliary sensing unit to drive an output line in response to the voltage of the bit line during a read operation. In some embodiments, the auxiliary sensing unit may include a differential amplifier arranged to compare the voltage of the bit line to a reference voltage. A method of reading a memory cell may include precharging a bit line, transferring charge from the memory cell to the bit line, activating a sense amplifier coupled to the bit line, and comparing the voltage of the bit line to a reference voltage.

### CROSS-REFERENCE TO RELATED APPLICATION

This application claims the benefit of Korean Patent Application No. 10-2005-0106395, filed on Nov. 8, 2005 which is incorporated by reference.

### BACKGROUND

In general, memory devices such as dynamic random access memory (DRAM) use charge sharing that occurs between a capacitance component of a bit line and a memory cell capacitor when data is written to or read from a memory cell. In particular, data can be read from the memory cell by sense-amplifying a voltage difference generated between two bit lines using charge sharing.

FIG. 1 is a prior art circuit diagram illustrating a semiconductor memory device having a conventional sense amplifier structure. Referring to FIG. 1, the semiconductor memory device includes a memory cell array 10, a sense amplifier 20, an equalization transistor unit 30, and a column select gate pair 40.

The memory cell array 10 includes a plurality of memory cells (not shown). Each memory cell includes a transistor which is gated by a word line voltage and a cell capacitor which stores data. When a memory cell to be written or read is connected to a first bit line BL 1, read and write operations are performed as follows.

First, the equalization transistor unit 30 is turned on by a precharge control signal PEQ, so bit lines BL1 and BL2 are precharged to a precharge voltage VBL.

Thereafter, a word line of the memory cell to be read is activated, and charge sharing occurs between a cell capacitor included in the memory cell and the first bit line BL1. As a result, a voltage difference is generated between the bit line pair BL1 and BL2. A pull-up transistor MP1 and a pull-down transistor MN1 are turned on by control signals LAPG and LANG, respectively. Through the operation of the sense amplifier 20, when high-level data is stored in the memory cell, the first bit line BL1 is driven to a pull-up voltage Vint, and the second bit line BL2 is driven to a pull-down voltage Vss. The pull-down voltage Vss is generally a ground voltage. A first column gate of the column select gate pair 40 is turned on by an activated first column selection signal CSL1, and transmits a voltage signal from the first bit line BL1 to a first input-output line IO1. Similarly, a second column gate is turned on by an activated second column selection signal CSL2, and transmits a voltage signal from the second bit line BL2 to a second input-output line IO2.

A write operation is performed in a similar manner to the read operation. Data signals input from the input-output lines IO1 and IO2 are transmitted through the first bit line BL1 of the memory cell array 10 via the column select gate pair 40.

If high-level data is to be written in the memory cell, a signal having a voltage corresponding to the pull-up voltage Vint is transmitted through the first input-output line IO1, and a signal having a voltage corresponding to the pull-down voltage Vss is transmitted through the second input-output line IO2.

The write operation will now be described with reference to FIG. 2 which is a prior art circuit diagram illustrating a general memory cell. Referring to FIG. 2, the memory cell includes a transistor T1 and a cell capacitor C1. A gate electrode of the transistor T1 is connected to a first word line WL1. A first electrode of the transistor T1 is connected to a first bit line BL1, and a second electrode of the transistor T1 is connected to the cell capacitor C1. The cell capacitor C1 is connected between a second electrode of the transistor T1 and a pull-down voltage Vss.

As described above, when high-level data is written to the memory cell, the pull-up voltage Vint is applied to the first electrode of the transistor T1. The transistor T1 is turned on by a word line voltage input to the first word line WL1, and the pull-up voltage Vint is applied to a first electrode of the capacitor C1. Accordingly, the capacitor C1 stores the high-level data.

If the word line WL1 were to be driven with the pull-up voltage Vint, the voltage Vc applied to the first electrode of the capacitor C1 would end up being lower than the pull-up voltage Vint due to the threshold voltage of the transistor T1. Therefore, a power supply voltage Vpp, which is higher than the pull-up voltage Vint, is generally used to drive the first word line WL1. The use of an elevated word line voltage, however, results in increased power consumption.

Meanwhile, the data stored in the memory cell may be lost due to leakage current. To prevent this, periodical refresh operations are required. In particular, high-level data is more vulnerable to leakage current than low-level data when stored in the memory cell.

As describe above, when a voltage corresponding to the pull-up voltage Vint is applied to a cell capacitor in order to store high-level data, data retention time decreases, and thus a refresh period also decreases. As the refresh period decreases, more power is required to retain the data.

### SUMMARY

Some of the inventive principles of this patent disclosure relate to a semiconductor memory device having a bit line coupled to a sense amplifier and an auxiliary sensing unit to drive an output line in response to the voltage of the bit line during a read operation. In some embodiments, the auxiliary sensing unit may include a differential amplifier arranged to compare the voltage of the bit line to a reference voltage.

Some additional inventive principles of this patent disclosure relate to a method of reading a memory cell in which charge is transferred from the memory cell to a bit line, a sense amplifier coupled to the bit line is activated, the voltage of the bit line is compared to a reference voltage, and an output line is driven in response to the comparison. The output line may be driven to a first state if the difference between the voltage of the bit line and the reference voltage is greater than or equal to a detection voltage, and driven to a second state if the difference is less than the detection voltage. In some embodiments, the sense amplifier may be activated before the voltage of the bit line is compared to the reference voltage during a read operation.

Some additional inventive principles of this patent disclosure relate to a memory device including an equalization transistor unit to precharge a pair of bit lines to a precharge voltage, a sense amplifier to sense a voltage difference between the bit lines, a pair of column select gates coupled between the bit lines and a pair of input-output lines, and a first differential amplifier having a first input coupled to a first one of the bit lines, a second input coupled to a reference voltage, and two outputs coupled to the input-output lines. The first differential amplifier may drive its outputs to a first state if the voltage difference between the first bit line and the reference voltage reaches a detection voltage, and to a second state if the difference does not reach the detection voltage. In some embodiments, the detection voltage includes a minimum detectable voltage difference between the first and second inputs of the first differential amplifier, and may further include an offset voltage of the first differential amplifier.

### BRIEF DESCRIPTION OF THE DRAWINGS

FIG. 1 is a circuit diagram illustrating a semiconductor memory device having a conventional sense amplifier structure.

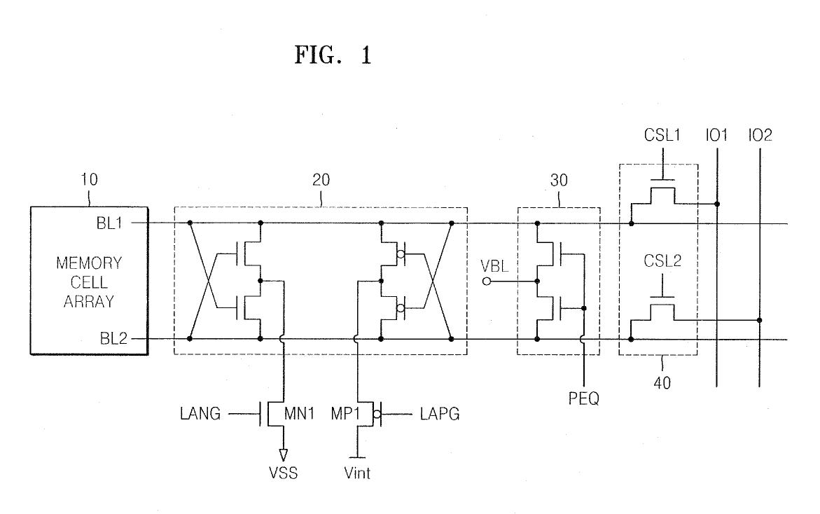

FIG. 2 is a circuit diagram illustrating a general memory cell.

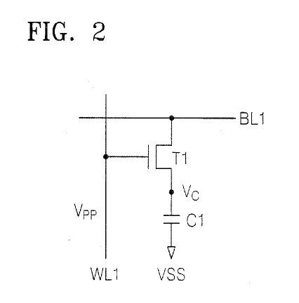

FIG. 3 is a circuit diagram illustrating an embodiment of a semiconductor memory device according to some of the inventive principles of this patent disclosure.

FIG. 4 is a timing diagram illustrating an embodiment of a data read operation of the semiconductor memory device of FIG. 3 according to some of the inventive principles of this patent disclosure.

FIG. 5 is a timing diagram illustrating an embodiment of a data write operation of the semiconductor memory device of FIG. 3 according to some of the inventive principles of this patent disclosure.

FIG. 6 is a block diagram illustrating an embodiment of an enable signal generator used in a semiconductor memory device according to some of the inventive principles of this patent disclosure.

### DETAILED DESCRIPTION

The attached drawings for illustrating exemplary embodiments of the present invention are referred to in order to gain a sufficient understanding, but the inventive principles are not limited to these exemplary embodiments.

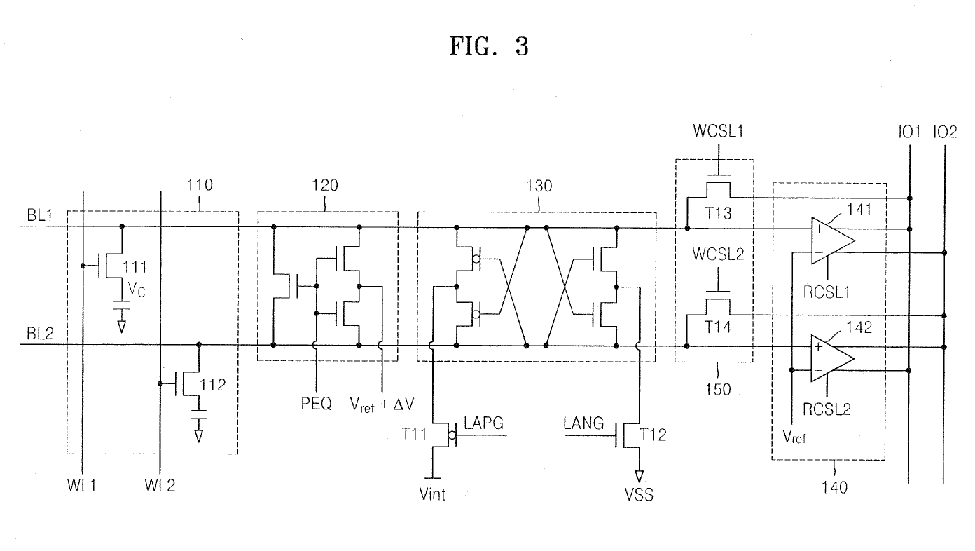

FIG. 3 is a circuit diagram illustrating an embodiment of a semiconductor memory device in accordance with some of the inventive principles of this patent disclosure. Referring to FIG. 3, the semiconductor memory device includes a memory cell array 110, an equalization transistor unit 120, a sense amplifier 130, a column select gate pair 150, and an auxiliary sensing unit which, in this embodiment, is implemented with a differential amplifier unit 140.

The memory cell array 110 includes a plurality of memory cells. For example, a first memory cell 111 and a second memory cell 112, which are respectively connected to bit line pair BL1 and BL2, are shown in FIG. 3. Each of the memory cells 111 and 112 includes a transistor and a cell capacitor. A voltage Vc is applied to a first electrode of the cell capacitor. A gate of the transistor in the first memory cell 111 is connected to a first word line WL1, and a gate of the transistor in the second memory cell 112 is connected to a second word WL2.

The equalization transistor unit 120 is connected to the bit line pair BL1 and BL2, and precharges the bit line pair BL1 and BL2 to a precharge voltage. The equalization transistor unit 120 is controlled by a precharge control signal PEQ. In the embodiment of FIG. 3, the precharge voltage corresponds to the sum of a reference voltage Vref and a detection voltage ΔV.

The sense amplifier 130 is connected between the bit line pair BL1 and BL2, and senses a voltage difference between the bit line pair BL1 and BL2. The sense amplifier 130 includes a PMOS transistor portion and an NMOS transistor portion. The PMOS transistor portion is connected to a pull-up transistor T11, which is gated by a pull-up control signal LAPG. Similarly, the NMOS transistor portion is connected to a pull-down transistor T12, which is gated by a pull-down control signal LANG.

The auxiliary sensing unit in the embodiment of FIG. 3 is implemented with a differential amplifier unit 140 which includes a first differential amplifier 141 and a second differential amplifier 142. A first input node of the first differential amplifier 141 is connected to the first bit line BL1, and a second input node thereof is connected to the reference voltage Vref. The output nodes of the first differential amplifier 141 are connected to an input-output line pair IO1 and IO2.

In addition, a first input node of the second differential amplifier 142 is connected to the second bit line BL2, and a second input node thereof is connected to the reference voltage Vref. The output nodes of the second differential amplifier 142 are connected to the input-output line pair IO1 and IO2.

The first differential amplifier 141 outputs a high-level data signal through the input-output line pair IO1 and IO2, when a voltage at the first bit line BL1 is higher than the reference voltage Vref by at least the detection voltage ΔV. In other words, when data stored in the memory cell 111 is high-level data, a signal having a voltage Vint is output through the first input-output line IO1, and a signal having a voltage Vss is output through the second input-output line IO2.

Similarly, the second differential amplifier 142 also outputs a high-level data signal through the input-output line pair IO1 and IO2, when a voltage at the second bit line BL2 is higher than the reference voltage Vref by at least the detection voltage ΔV. In other words, when data stored in the memory cell 112 is high-level data, the signal having the voltage Vss is output through the first input-output line IO1, and the signal having the voltage Vint is output through the second input-output line IO2.

A first enable signal RCSL1 controls the operation of the first differential amplifier 141 and a second enable signal RCSL2 controls the operation of the second differential amplifier 142.

The column select gate pair 150 is connected to the bit line pair BL1 and BL2 and the input-output line pair IO1 and IO2. A first column gate T13 may be coupled between the first bit line BL1 and the first input-output line IO1, and a second column gate T14 may be coupled between the second bit line BL2 and the second input-output line IO2.

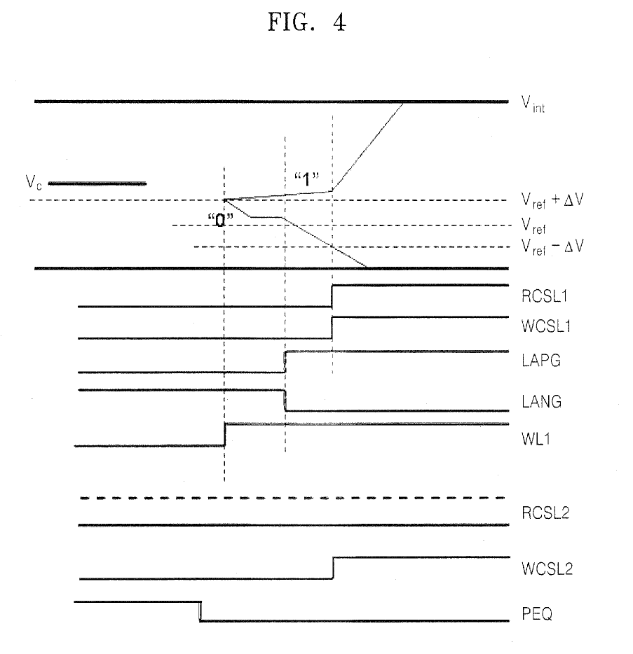

The operation of the semiconductor memory device having the aforementioned structure according to an embodiment of the present invention will now be described with reference to FIG. 4.

FIG. 4 is a timing diagram illustrating a data read operation of the semiconductor memory device of FIG. 3 in accordance with some of the inventive principles of this patent disclosure. The timing diagram shows a case where data of the memory cell 111 connected to the first bit line BL1 is read.

Referring to FIG. 4, a precharge control signal PEQ is first activated, which turns on the transistors of the equalization transistor unit 120. As a result, the bit line pair BL1 and BL2 is precharged to a specific precharge voltage. When the bit line pair BL1 and BL2 is precharged, the precharge voltage becomes equal to a sum of a reference voltage Vref and a detection voltage ΔV.

The detection voltage ΔV may be at least equal to a minimum voltage difference detectable by a differential amplifier included in the differential amplifier unit 140. The minimum voltage difference may include an offset voltage of the differential amplifier. For example, when the minimum detectable voltage difference of the differential amplifier is 100 mV under normal operating conditions, and the offset voltage of the differential amplifier is 30 mV, then the detection voltage ΔV has to be 130 mV or higher. In this case, the precharge voltage becomes the sum of the reference voltage Vref and 130 mV.

After the precharge operation of the bit line pair BL1 and BL2 is completed based on the aforementioned precharge voltage, the precharge control signal PEQ is deactivated. Thereafter, a first word line WL1 is activated to read data of the first memory cell 111. This turns on the transistor included in the first memory cell 111 and thus charge sharing occurs between the cell capacitor of the first memory cell 111 and a capacitance component of the first bit line BL1.

In order for the first memory cell 111 to be read as high-level data, the voltage Vc stored in the cell capacitor has to be equal to or greater than the sum of the reference voltage Vref and the detection voltage ΔV. This is because, when a first bit line voltage input to a first input node of the first differential amplifier 141 is greater than the reference voltage Vref by at least as much as the detection voltage ΔV, the first differential amplifier 141 outputs a high-level data signal through a differential amplification of the two input signals.

Thereafter, a pull-up control signal LAPG and a pull-down control signal LANG are activated, thereby enabling the sense amplifier 130. Here, if the voltage Vc stored in the cell capacitor of the first memory cell 111 is Vref+ΔV, the first bit line voltage is almost equal to the voltage stored in the cell capacitor. Thus, even after charge sharing occurs, the first bit line voltage is maintained at approximately the level of Vref+ΔV.

Thereafter, the first enable signal RCSL1 is activated, thereby enabling the first differential amplifier 141 of the differential amplifier unit 140. In addition, the first column select signal WCSL1 and the second column select signal WSCL2 are activated, thereby turning on first and second column select gates T13 and T14 of the column select gate pair 150, respectively.

As described above, in the first differential amplifier 141, a first bit line voltage is input to a positive input node, and a reference voltage Vref is input to a negative input node. If the first bit line voltage is greater than the reference voltage Vref by at least as much as the detection voltage ΔV, a high-level data signal is output through the input-output line pair IO1 and IO2. Accordingly, if the first bit line has a voltage of Vref+ΔV or more, the first differential amplifier 141 amplifies the voltage (the first bit line voltage and the reference voltage) input to the two input nodes, and outputs the high-level data signal through the input-output line pair IO1 and IO2. An output node of the first differential amplifier 141 is connected to the input-output line pair IO1 and IO2. When a high-level data signal is the output, the output node of the first differential amplifier 141 may output a voltage signal corresponding to Vint through the first input-output line IO1, and output a voltage signal corresponding to Vss through the second input-output line IO2.

Even when the charge stored in the capacitor of memory cell 111 is partially lost due to a leakage current after the capacitor is charged to the voltage Vint to store high-level data in the first memory cell 111, the semiconductor memory device may detect that the data stored in the first memory cell 111 is high-level as long as the voltage of the cell capacitor is equal to or greater than Vref+ΔV. In other words, even if charge stored in the cell capacitor is lost to some extent, the data can be accurately detected, and thus a refresh period for preserving the data can be extended. The more the reference voltage Vref drops, the more the data is accurately detected, even when the charge is lost significantly.

Further, since the data can be accurately detected even if the charge loss is significant in the cell capacitor, a word line voltage connected to the memory cell can be lowered. For example, for the first word line WL1 voltage input to a gate electrode of the transistor included in the first memory cell 111, the pull-up voltage Vint may be input which is lower than the power supply voltage Vpp which is conventionally used. This is because the data stored in the memory cell can be detected even when a voltage applied to a first electrode of the cell capacitor decreases due to a threshold voltage of the transistor.

By respectively turning on the first and second column select gates T13 and T14 of the column select gate pair 150, a voltage signal output through the input-output line pair IO1 and IO2 can be transmitted to the first memory cell 111. This is a write back operation, through which the data of the first memory cell 111 can be prevented from being lost right after a data read operation.

Even when low-level data is stored in the first memory cell 111, the data can be read by the aforementioned operation. In the process of reading the low-level data, charge sharing occurs between the cell capacitor of the first memory cell 111 and the first bit lint BL1, and a voltage of the first bit lint BL1 decreases.

Referring to FIG. 4, when the low-level data (data “0”) is read, a sufficient voltage difference is generated between the bit line pair BL1 and BL2 due to the charge sharing, and thus the sense amplifier 130 carries out an amplification operation. As a result, the first bit line voltage input to a first input node of the first differential amplifier 141 becomes lower than the reference voltage Vref by as much as the detection voltage ΔV. In this case, the first differential amplifier 141 outputs the low-level data signal through the input-output line pair IO1 and IO2. As shown in FIG. 4, when the low-level data is read, after the first bit line voltage becomes lower than the reference voltage Vref by as much as the detection voltage ΔV, the first enable signal RCSL1 may be activated to enable the first differential amplifier 141.

The operation of the first memory cell 11 of FIG. 3 has been described above. The second memory cell 112 and other memory cells (not shown) may perform the same operation to achieve the same effect.

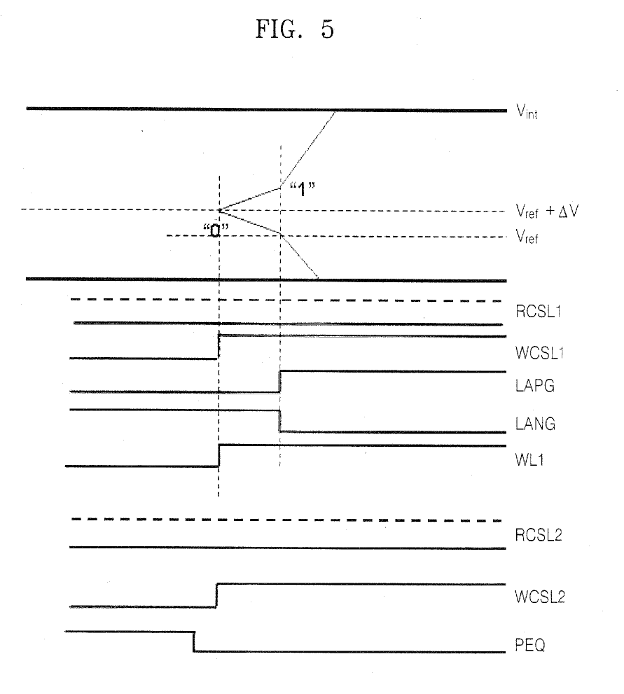

Now, a data write operation of the semiconductor memory device will be described with reference to FIG. 5. The write operation will be described with reference to the first memory cell 111, but similar operations can be performed for other cells as well.

FIG. 5 is a timing diagram illustrating a data write operation of the semiconductor memory device of FIG. 3 in accordance with some of the inventive principles of this patent disclosure. Referring to FIG. 5, a first word line W1, is activated after a precharge operation is completed, and a first column select signal WCSL1 and a second column select signal WCSL2 are activated. As a result, the column select gate pair 150 turns on.

A data signal input through the input-output line pair IO1 and IO2 is input to the bit line pair BL1 and BL2 through the column select gate pair 140. A voltage difference is generated between the bit line pair BL1 and BL2.

Thereafter, a pull-up control signal LAPG and a pull-down control signal LANG are activated, thereby turning on the pull-up transistor T11 and the pull-down transistor T12, and data is stored in the memory cell 111 by using a voltage of an amplified bit line pair BL1 and BL2. In the process of the data write operation, the first enable signal RCSL1 and the second enable signal RCSL2 are respectively deactivated, and thus the differential amplifier unit 140 does not operate.

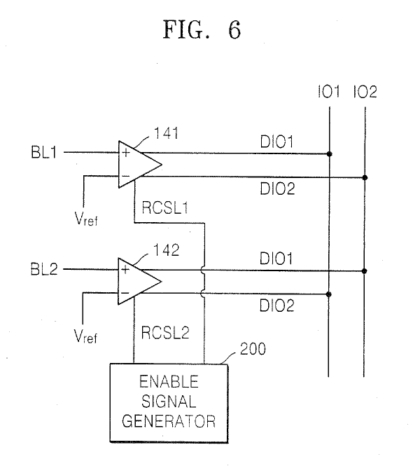

FIG. 6 is a block diagram illustrating an enable signal generator used in a semiconductor memory device according to an embodiment of the present invention. An enable signal generator 200 outputs a first enable signal RCSL1 to a first differential amplifier 141, and outputs a second enable signal RCSL2 to a second differential amplifier 142. The first differential amplifier 141 generates signals DIO1 and DIO2 according to a differential amplification operation, and outputs the signals DIO1 and DIO2 to an input-output line pair IO1 and IO2, respectively. The second differential amplifier 142 also outputs the signals DIO1 and DIO2 through the input-output line pair IO1 and IO2.

During a read operation of the first memory cell 111, the enable signal generator 200 outputs an activated first enable signal RCSL1, and outputs a deactivated second enable signal RCSL2. As a result, the first differential amplifier 141 is enabled, and the second differential amplifier 142 is disabled.

Further, in a read operation of the second memory cell 112, the enable signal generator 200 deactivates the first enable signal RCSL1 and activates the second enable signal RCSL2. As a result, the first differential amplifier 141 is disabled, and the second differential amplifier 142 is enabled.

On the other hand, in a write operation of the first and second memory cells 111 and 112, both the first and second enable signals RCSL1 and RCSL2 are deactivated. As a result, the first differential amplifier 141 and the second differential amplifier 142 are disabled.

Accordingly, in the present invention, a word line may be driven at a low voltage, and even if charge stored in a cell capacitor is lost to some extent, the data may be accurately sensed. Moreover, refresh rate of the capacitor may also be reduced. Therefore, less power may be consumed, and data retention features may be improved.

While the inventive principles of this patent disclosure have been particularly shown and described with reference to exemplary embodiments thereof, it will be understood by those skilled in the art that various changes in form and details may be made therein without departing from the scope of the present invention as defined by the appended claims.

1. A memory device comprising:
an equalization transistor unit to precharge a pair of bit lines to a precharge voltage;
a sense amplifier to sense a voltage difference between the bit lines;
a pair of column select gates coupled between the bit lines and a pair of input-output lines; and
a first differential amplifier having a first input coupled to a first one of the bit lines, a second input coupled to a reference voltage, and two outputs coupled to the input-output lines.

2. The memory device of claim 1, wherein the first differential amplifier outputs a high level or low level data signal if the voltage difference between the first bit line and the reference voltage reaches a detection voltage.

3. The memory device of claim 2, wherein the detection voltage includes a minimum detectable voltage difference between the first and second inputs of the first differential amplifier.

4. The memory device of claim 3, wherein the detection voltage further includes an offset voltage of the first differential amplifier.

5. The memory device of claim 1, further comprising a second differential amplifier having a first input coupled to a second one of the bit lines, a second input coupled to the reference voltage, and two outputs coupled to the input-output lines.

6. The memory device of claim 5, wherein the first differential amplifier may be enabled by a first enable signal and the second differential amplifier may be enabled by a second enable signal.

7. The memory device of claim 2, wherein the precharge voltage corresponds to the sum of the reference voltage and the detection voltage.

8. The memory device of claim 2, wherein a word line voltage that activates a memory cell coupled to the bit line is substantially equal to a pull-up voltage of the sense amplifier.

9. The memory device of claim 2, wherein a word line voltage that activates a memory cell coupled to the bit line is greater than a pull-tip voltage of the sense amplifier.

10. The memory device of claim 6, further comprising an enable signal generator to activate one of the enable signals and deactivate the other enable signal during a read operation.

11. The memory device of claim 1, wherein the memory device comprises a dynamic random access memory (DRAM).

12. A method of reading a memory cell, the method comprising:
precharging a bit line to a precharge voltage;
transferring charge from the memory cell to the bit line;
activating a sense amplifier coupled to the bit line;
comparing the voltage of the bit line to a reference voltage; and
driving an output line in response to the comparison.

13. The method of claim 12, wherein transferring charge from the memory cell to the bit line comprises activating a word line coupled to the memory cell.

14. The method of claim 13, wherein the voltage applied to the word line is no greater than a pull-up voltage.

15. The method of claim 12, wherein driving the output line in response to the comparison comprises outputting a high-level or a low-level data signal if the difference between the voltage of the bit line and the reference voltage is greater than or equal to a detection voltage.

16. The method of claim 12, further comprising performing a write-back operation on the memory cell.

17. The method of claim 12, wherein the sense amplifier is activated before the voltage of the bit line is compared to the reference voltage during a read operation.

18. A semiconductor memory device comprising:
a bit line to read a memory cell;
a sense amplifier coupled to the bit line; and
an auxiliary sensing unit coupled to the bit line to drive an output line in response to the voltage of the bit line during a read operation.

19. The memory device of claim 18 wherein the auxiliary sensing unit comprises a differential amplifier having a first input coupled to the bit line, a second input coupled to a reference voltage, and an output to drive the output line.

20. The memory device of claim 18 wherein the auxiliary sensing unit comprises means for comparing the voltage of the bit line to a reference voltage.
